(19) United States
(12) Patent Application Publication
(10) Pub. No.: US 2009/0009193 A1
(43) Pub. Date: Jan. 8, 2009

(54) Moisture-Sensitive Element with an Interdigital Capacitor and Fabrication thereof

(75) Inventors: Shen-Kan Hsiung, Tao-Yuan (TW); Jung-Chuan Chou, Tao-Yuan (TW); Tai-Ping Sun, Tao-Yuan (TW); Ting-Hsiang Huang, Tao-Yuan (TW)

Correspondence Address: WPAT, PC, 7225 BEVERLY ST., ANNANDALE, VA, 22003, US

(73) Assignee: CHUNG YUAN CHRISTIAN UNIVERSITY, Tao-Yuan (TW)

(21) Appl. No.: 11/774,541

(22) Filed: Jul. 6, 2007

(51) Int. Cl. G01R 27/26; H05K 3/30

(52) U.S. Cl. 324/664; 29/832

(57) ABSTRACT

A moisture-sensitive element with an interdigital capacitor (IDC) and fabrication thereof are disclosed, wherein the moisture-sensitive element with the interdigital capacitor investigates a moisture sensor for the determination of human skin moisture based on the interdigital capacitor. The moisture-sensitive element with an interdigital capacitor comprises a printed circuit board (PCB), an interdigital capacitor formed on the printed circuit board, and a moisture sensing layer formed on the interdigital capacitor.

### BACKGROUND OF THE INVENTION

1. Field of the Invention

The present invention is generally related to a moisture-sensitive element, and more particularly to a moisture-sensitive element with an interdigital capacitor.

2. Description of the Prior Art

Research on moisture-sensitive elements has been developed for years. In the areas of automation development, living quality promotion, and environmental quality, sensing elements are necessary. Generally, moisture-sensitive elements are utilized in environmental monitoring and control. For example, the common seen moisture-sensitive element is the household electronic thermo-hygrometer, dehumidifier, hygrostat, etc. However, not only air contains moisture but also a general living body has water content. Especially, due to development of biotechnology and prosperousness in cosmetic industry, the technique of moisture-sensitive elements has been applied in determining skin moisture content. Applying the technique of moisture-sensitive elements in cosmetic medical field is an important subject to be solved.

### SUMMARY OF THE INVENTION

In light of the above mentioned background, the present invention provides a moisture-sensitive element with an interdigital capacitor to overcome the above disadvantages of a traditional moisture-sensitive element.

Generally, sensing elements has two major categories, capacitance type and resistance type. The invention basically uses a printed circuit board to make interdigital electrodes and then uses the hot pressing method to fix polyimide film on the electrodes to thereby fabricate a capacitance type sensing element with two sensing functionalities, determining environment relative humidity and skin cuticle moisture content. In addition, the invention discusses the effect of the shape of interdigital electrodes on the basic capacitance of the sensing element and sensing characteristic and finds out the suitable interdigital electrodes for environmental and skin measurements.

One object of the present invention is to provide a moisture-sensitive element with an interdigital capacitor, comprising a printed circuit board (PCB), an interdigital capacitor, and a sensing layer. The interdigital capacitor is formed on the printed circuit board. The sensing layer is formed on the interdigital capacitor. The interdigital capacitor comprises a first electrode and a second electrode. The first electrode comprises a plurality of first extending electrodes and the second electrode comprises a plurality of second extending electrodes. The plurality of second extending electrodes are provided interlaced with the plurality of first extending electrodes, i.e. the neighboring electrode of the first extending electrode is the second extending electrode and the neighboring electrode of the second extending electrode is the first extending electrode. Each first extending electrode together with its neighboring second extending electrode form a pair of extending electrodes. Furthermore, by electrically coupling the first electrode and the second electrode to a LCR meter (inductance-capacitance-resistance meter), a moisture-sensitive system with an interdigital capacitor is formed to measure environment moisture and skin moisture content.

In addition, the method for fabricating the moisture-sensitive element with the interdigital capacitor comprises the following steps: providing the printed circuit board (PCB); forming the interdigital capacitor on the printed circuit board by etching via double-side printed circuit board technique; and mounting the sensing layer on the interdigital capacitor by hot pressing.

Furthermore, the method for determining skin moisture by the moisture-sensitive system with the interdigital capacitor comprises the following steps: placing the moisture-sensitive element with the interdigital capacitor on the skin; absorbing the moisture on the skin by the sensing layer and thus changing an output capacitance value of the interdigital capacitor; and receiving and measuring the output capacitance value by the LCR meter to determine the moisture content of the skin.

### BRIEF DESCRIPTION OF THE DRAWINGS

FIG. 1 shows a schematic diagram illustrating the structure of a moisture-sensitive element with an interdigital capacitor;

FIG. 2 shows a schematic diagram illustrating the structure of an interdigital capacitor;

FIG. 3 shows a schematic diagram illustrating the structure of a moisture-sensitive system with an interdigital capacitor; and

FIGS. 4 and 5 show schematic diagrams illustrating the experimental data of a moisture-sensitive system with an interdigital capacitor.

### DESCRIPTION OF THE PREFERRED EMBODIMENTS

What is probed into the invention is a moisture-sensitive element with an interdigital capacitor. Detail descriptions of the structure and elements will be provided in the following in order to make the invention thoroughly understood. Obviously, the application of the invention is not confined to specific details familiar to those who are skilled in the art. On the other hand, the common structures and elements that are known to everyone are not described in details to avoid unnecessary limits of the invention. Some preferred embodiments of the present invention will now be described in greater detail in the following. However, it should be recognized that the present invention can be practiced in a wide range of other embodiments besides those explicitly described, that is, this invention can also be applied extensively to other embodiments, and the scope of the present invention is expressly not limited except as specified in the accompanying claims.

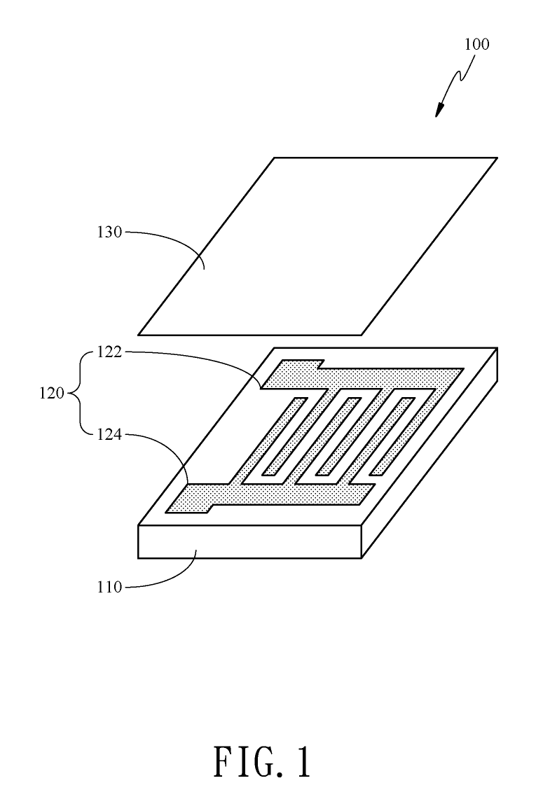

FIG. 1 shows a schematic diagram illustrating the structure of a moisture-sensitive element 100 with an interdigital capacitor. The moisture-sensitive element 100 comprises a printed circuit board (PCB) 110, an interdigital capacitor 120, and a sensing layer 130. The interdigital capacitor 120 is formed on the printed circuit board 110. The sensing layer 130 is formed on the interdigital capacitor 120.

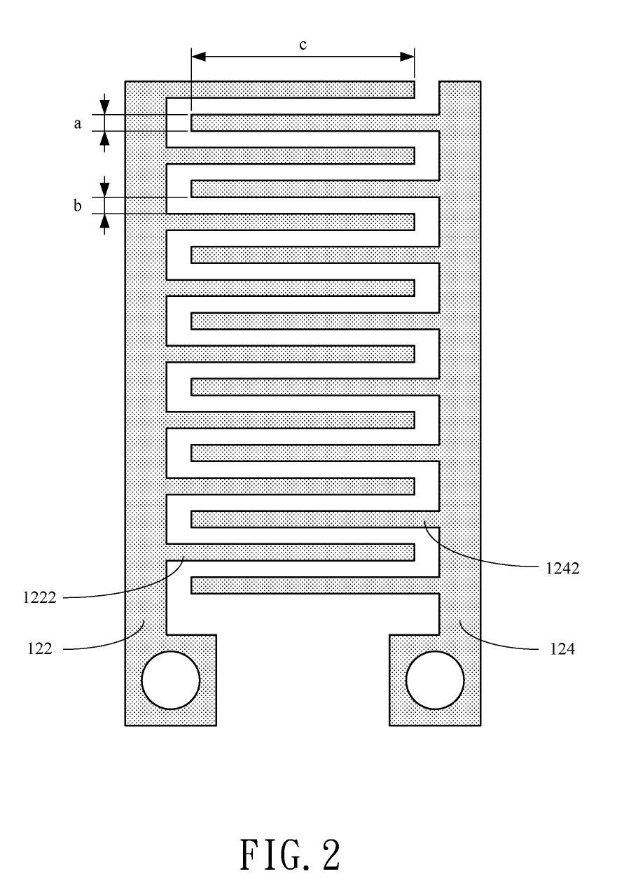

The sensitivity of such moisture-sensitive element depends on not only the sensing layer 130 but also the structure of the electrodes. Therefore, the interdigital capacitor 120 according to the invention further promotes the sensitivity of the moisture-sensitive element 100. As shown in FIG. 2, the interdigital capacitor 120 comprises a first electrode 122 and a second electrode 124. The first electrode 122 comprises a plurality of first extending electrodes 1222 and the second electrode 124 comprises a plurality of second extending electrodes 1242. The plurality of second extending electrodes 1242 are provided interlaced with the plurality of first extending electrodes 1222, i.e. the neighboring electrode of the first extending electrode 1222 is the second extending electrode 1242 and the neighboring electrode of the second extending electrode 1242 is the first extending electrode 1222. Each first extending electrode 1222 together with its neighboring second extending electrode 1242 form a pair of extending electrodes.

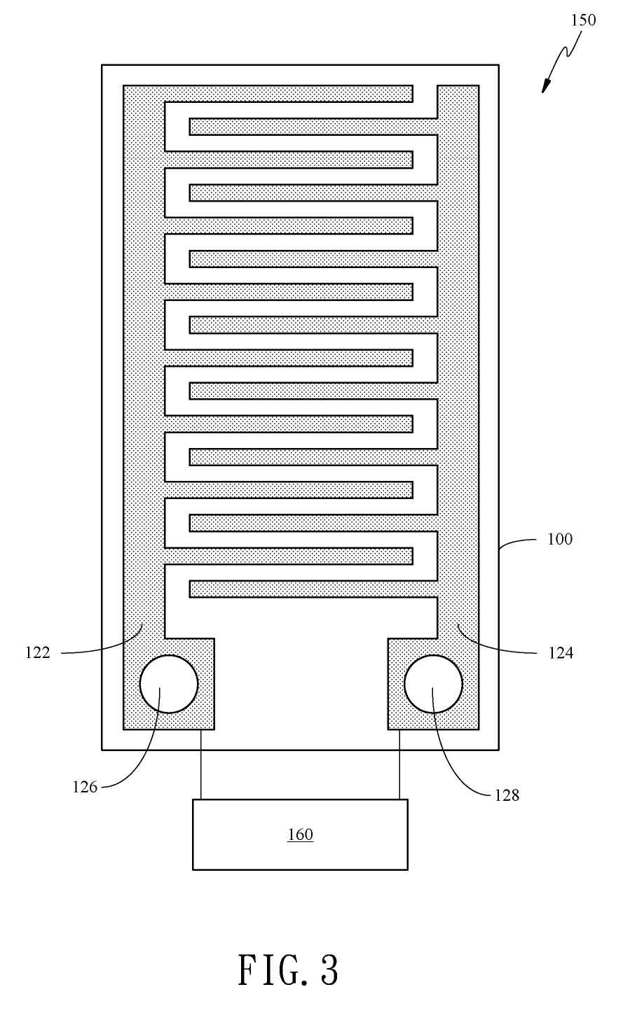

FIG. 3 shows a schematic diagram illustrating the structure of a moisture-sensitive system 150 with an interdigital capacitor. The moisture-sensitive system 150 comprises the moisture-sensitive element 100 with the interdigital capacitor and a LCR meter 160. The first electrode 122 is electrically coupled to the LCR meter 160 via a first terminal 126 and the second electrode 124 is electrically coupled to the LCR meter 160 via a second terminal 128.

As the moisture-sensitive element 100 with the interdigital capacitor is power-on, an electric field is produced between the first electrode 122 and the second electrode 124 of the interdigital capacitor 120 to have capacity effect. The dielectric constant of water is about 80. Thus, if water enters the electric field, the total dielectric constant increases for the interdigital capacitor 120 due to water molecules and thus the output capacitance is increased. The more is the water content, the more is the change of the capacitance. Therefore, the amount of capacitance change measured by the LCR meter 160 can determine the amount of water content.

According to the above, the invention provides a method for determining skin moisture by the moisture-sensitive system with the interdigital capacitor, comprising the following steps: at first placing the moisture-sensitive element 100 with the interdigital capacitor on the skin; absorbing the moisture on the skin by the sensing layer 130 to thus change an output capacitance value of the interdigital capacitor 120; and receiving and measuring the output capacitance value by the LCR meter 160 to determine the moisture content of the skin.

However, the geometrical structure of the interdigital capacitor 120 has many variable parameters. For example, the width of the first extending electrode 1222 and the second extending electrode 1242 is a, the pitch between the first extending electrode 1222 and its neighboring second extending electrode 1242 is b, and the interlaced overlapping length of the first extending electrode 1222 and the second extending electrode 1242 is c, as shown in FIG. 2.

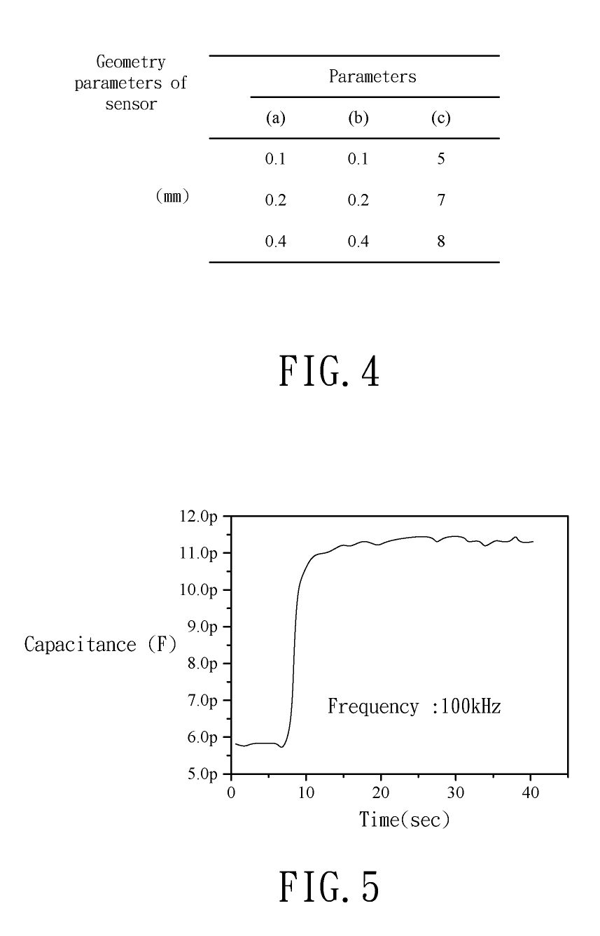

FIG. 4 shows 27 different types of geometrical structures by taking three different values for each parameter described in the above. After experiments, the following better parameters are obtained and thus better measurement efficiency of the interdigital capacitor 120 is achieved. The width a of the first electrode 1222 and the second electrode is 0.2 mm. The pitch b between the first extending electrode 1222 and its neighboring second extending electrode 1242 is 0.2 mm. The interlaced overlapping length c of the first extending electrode 1222 and the second extending electrode 1242 is 7 mm. Besides, the interdigital capacitor 120 comprises eight pairs of extending electrodes for better capacity effect.

Moreover, the experiments are carried out in environment of 23±1° C. and 45±2%R.H. The LCR meter 160 can be HP4284A LCR meter, the frequency range of which is between 1 kHz and 1 MHz and the applied voltage of which is 3V.

The initial capacitance value of the LCR meter 160 before measurement is 5.8 pF. When the moisture-sensitive element 100 with the interdigital capacitor is placed on skin, the capacitance measured by the LCR meter 160 starts to increase. According to the experimental result, the measured stable capacitance value is 11.3 pF. Thus, the difference in capacitance value is 5.5 pF and the sensing time is about 3 seconds, as shown in FIG. 5.

Furthermore, the invention provides a method for fabricating a moisture-sensitive element with an interdigital capacitor, comprising the following steps. At first, the printed circuit board (PCB) 110 is provided. The PCB 110 is used to form complicate copper circuitry among electronic parts by etching an organized pattern thereon to provide support and installation for electronic parts and is a basic component for almost all electronic products. The PCB 110 is a plate made by insulating material. Generally, the plate is provides with holes for mounting chips and other electronic elements. The holes and the metallic paths pre-printed on the plate make electronic elements thereon easily electrically connected. For example, the pins of the electronic element go through the holes on the PCB 110 and then can be mounted on the PCB 110 by soldering to form circuitry. According to application fields, the PCB 110 can be a one-side plate, double-side plate, multi-layer plate more than four layers, and flexible plate.

Then, the printed circuit board technique is used to form the interdigital capacitor 120 on the PCB 110 by etching. The first terminal 126 of the first electrode 122 and the second terminal 128 of the second electrode 124 are printed on two surfaces of the PCB 110 by etching. The first electrode 122 of the interdigital capacitor 120 is provided on one side of the PCB 110 and the second electrode 124 is provided on the other side of the PCB 110, in order to maintain the flatness of the sensing area. The first electrode 122 and the second electrode 124 are electrically coupled to the LCR meter 160 via the first terminal 126 and the second terminal 128 on the back of the PCB 110, respectively, to ensure the front smoothness of the PCB 110. Thus, during measurement, the inaccuracy due to uneven contact area can be prevented.

Finally, the sensing layer 130 is mounted on the interdigital capacitor 120 by hot pressing. The problem of uneven film thickness or difficulty in controlling film thickness by the dipping or spin coating method can be solved. Besides, the hot pressing method is relatively easy. The material of the interdigital capacitor 120 comprises copper and the material of the sensing layer 130 comprises polyimide. Polyimide has the polar group and thus is easy to absorb moisture to enhance the measurement of moisture content. In addition, polyimide does not fall off while contacting with skin and has the advantages of reusability, easy fabrication, and low cost compared to the flexible PCB.

The moisture-sensitive element 100 with an interdigital capacitor can measure the environment moisture and the human skin moisture. It can be placed in common air environment to measure surrounding environment moisture and can measure the moisture content of the skin cuticle if contacting with skin. In addition, this moisture-sensitive element is not influenced by temperature within the temperature range around 10° C.˜30° C. Thus, the skin moisture measurement can be conducted at the common room temperature.

In monitoring the environment moisture, the moisture-sensitive element 100 with an interdigital capacitor fabricated according to the invention can be utilized in the measure range of 50%R.H.˜95%R.H. In measuring the moisture content of the skin cuticle, it can measure common type and moist type skin. While measuring skin moisture, the moisture-sensitive element 100 with an interdigital capacitor can monitor the environment moisture at the same time to ensure the correctness of the skin moisture measurement.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A moisture-sensitive element with an interdigital capacitor, comprising:
a printed circuit board (PCB);
an interdigital capacitor formed on said printed circuit board; and
a sensing layer formed on said interdigital capacitor;
wherein said interdigital capacitor comprises:
a first electrode comprising a plurality of first extending electrodes; and
a second electrode comprising a plurality of second extending electrodes provided interlaced with said plurality of first extending electrodes wherein each first extending electrode together with its neighboring second extending electrode form a pair of extending electrodes.

2. The element according to claim 1, wherein the neighboring electrode of said first extending electrode is said second extending electrode and the neighboring electrode of said second extending electrode is said first extending electrode.

3. The element according to claim 1, wherein said interdigital capacitor comprises eight pairs of extending electrodes.

4. The element according to claim 1, wherein the width of said first extending electrode and said second extending electrode is 0.2 mm.

5. The element according to claim 1, wherein the pitch between said first extending electrode and its neighboring second extending electrode is 0.2 mm.

6. The element according to claim 1, wherein the interlaced overlapping length of said first extending electrode and said second extending electrode is 7 mm.

7. The element according to claim 1, wherein the material of said interdigital capacitor comprises copper.

8. The element according to claim 1, wherein the material of said sensing layer comprises polyimide.

9. A moisture-sensitive system with an interdigital capacitor, comprising:
a moisture-sensitive element with said interdigital capacitor and a LCR meter (inductance-capacitance-resistance meter);
wherein said moisture-sensitive element comprises:
a printed circuit board (PCB);
an interdigital capacitor formed on said printed circuit board; and
a sensing layer formed on said interdigital capacitor wherein said interdigital capacitor comprises:
a first electrode comprising a plurality of first extending electrodes and a first terminal; and
a second electrode comprising a plurality of second extending electrodes provided interlaced with said plurality of first extending electrodes and a second terminal wherein each first extending electrode together with its neighboring second extending electrode form a pair of extending electrodes; and
said first electrode is electrically coupled to said LCR meter via said first terminal and said second electrode is electrically coupled to said LCR meter via said second terminal.

10. The system according to claim 9, wherein the neighboring electrode of said first extending electrode is said second extending electrode and the neighboring electrode of said second extending electrode is said first extending electrode.

11. The system according to claim 9, wherein said interdigital capacitor comprises eight pairs of extending electrodes.

12. The system according to claim 9, wherein the width of said first extending electrode and said second extending electrode is 0.2 mm.

13. The system according to claim 9, wherein the pitch between said first extending electrode and its neighboring second extending electrode is 0.2 mm.

14. The system according to claim 9, wherein the interlaced overlapping length of said first extending electrode and said second extending electrode is 7 mm.

15. The system according to claim 9, wherein the material of said interdigital capacitor comprises copper.

16. The system according to claim 9, wherein the material of said sensing layer comprises polyimide.

17. The system according to claim 9, wherein the initial capacitance of said LCR meter is 5.8 pF.

18. A method for fabricating a moisture-sensitive element with an interdigital capacitor, comprising:
providing a printed circuit board (PCB);
forming an interdigital capacitor on said printed circuit board by etching via printed circuit board technique wherein said interdigital capacitor comprises:
a first electrode comprising a plurality of first extending electrodes and a first terminal; and
a second electrode comprising a plurality of second extending electrodes provided interlaced with said plurality of first extending electrodes and a second terminal wherein each first extending electrode together with its neighboring second extending electrode form a pair of extending electrodes and said first terminal and said second terminal are printed on two surfaces of said printed circuit board by etching via printed circuit board technique; and
mounting a sensing layer on said interdigital capacitor by hot pressing.

19. The method according to claim 18, wherein the neighboring electrode of said first extending electrode is said second extending electrode and the neighboring electrode of said second extending electrode is said first extending electrode.

20. The method according to claim 18, wherein said interdigital capacitor comprises eight pairs of extending electrodes.

21. The method according to claim 18, wherein the width of said first extending electrode and said second extending electrode is 0.2 mm.

22. The method according to claim 18, wherein the pitch between said first extending electrode and its neighboring second extending electrode is 0.2 mm.

23. The method according to claim 18, wherein the interlaced overlapping length of said first extending electrode and said second extending electrode is 7 mm.

24. The method according to claim 18, wherein the material of said interdigital capacitor comprises copper.

25. The method according to claim 18, wherein the material of said sensing layer comprises polyimide.

26. A method for determining skin moisture with an interdigital capacitor, comprising:
placing a moisture-sensitive element with said interdigital capacitor on the skin wherein said moisture-sensitive element comprises:
a printed circuit board (PCB);
an interdigital capacitor formed on said printed circuit board; and
a sensing layer formed on said interdigital capacitor wherein said interdigital capacitor comprises:
a first electrode comprising a plurality of first extending electrodes and a first terminal; and
a second electrode comprising a plurality of second extending electrodes provided interlaced with said plurality of first extending electrodes and a second terminal wherein each first extending electrode together with its neighboring second extending electrode form a pair of extending electrodes;
absorbing the moisture on the skin by said sensing layer to change an output capacitance value of said interdigital capacitor; and
receiving and measuring said output capacitance value by a LCR meter to determine the moisture content of the skin.

27. The method according to claim 26, wherein the neighboring electrode of said first extending electrode is said second extending electrode and the neighboring electrode of said second extending electrode is said first extending electrode.

28. The method according to claim 26, wherein said interdigital capacitor comprises eight pairs of extending electrodes.

29. The method according to claim 26, wherein the width of said first extending electrode and said second extending electrode is 0.2 mm.

30. The method according to claim 26, wherein the pitch between said first extending electrode and its neighboring second extending electrode is 0.2 mm.

31. The method according to claim 26, wherein the interlaced overlapping length of said first extending electrode and said second extending electrode is 7 mm.

32. The method according to claim 26, wherein the material of said interdigital capacitor comprises copper.

33. The method according to claim 26, wherein the material of said sensing layer comprises polyimide.

34. The method according to claim 26, wherein the initial capacitance of said LCR meter is 5.8 pF.
